(19) United States
(12) Patent Application Publication
(10) Pub. No.: US 2016/0336324 A1
(43) Pub. Date: Nov. 17, 2016

(54) TUNNEL FIELD EFFECT TRANSISTOR AND METHOD OF MAKING THE SAME

(71) Applicant: QUALCOMM Incorporated, San Diego, CA (US)

(72) Inventors: Xia LI, San Diego, CA (US); Bin YANG, San Diego, CA (US)

(21) Appl. No.: 14/713,712

(22) Filed: May 15, 2015

(51) Int. Cl. H01L 27/092; H01L 29/10; H01L 21/265; H01L 21/02; H01L 29/78; H01L 29/423; H01L 21/8238; H01L 27/088; H01L 29/66

(52) U.S. Cl. CPC H01L 27/0928; H01L 27/088; H01L 29/1037; H01L 21/26513; H01L 29/66977; H01L 29/7827; H01L 29/42376; H01L 21/823885; H01L 21/823892; H01L 29/66545; H01L 21/02164; H01L 21/0217

(57) ABSTRACT

A vertically integrated transistor device increases the effective active area of the device to improve the performance characteristics of the device. The transistor device may include a plurality of gate elements, a plurality of source-drain elements extending parallel to the plurality of gate elements and horizontally spaced therefrom; and a plurality of fin elements extending parallel to the plurality of gate elements and vertically spaced therefrom, wherein each of the plurality of fin elements is horizontally spaced a first distance from each of the other ones of the plurality of fin elements.

### FIELD OF DISCLOSURE

This disclosure relates generally to tunnel field effect transistor, and more specifically, but not exclusively, to FinFETs.

### BACKGROUND

CMOS technology has been scaling down in size for 40 years under the guidance of Moore's law. To continue scaling, a high-k metal gate stack, strain, and non-planar architectures have been added to the Si platform to enhance the drive current while suppressing short channel effects. However, regular CMOC scaling runs into a Vdd limit of ˜0.5V and cannot further scale power substantially with traditional CMOS transistors. Alternative approaches that can compare favorably with scaled CMOS are needed. One such alternative is tunnel field-effect transistors (TFETs). It has been understood that TFETs have advantages for low-power applications because of its' intrinsic low sub-threshold swing and low off-state leakage. One of the most promising candidate beyond traditional CMOS is a TFET to enable Vdd down to 0.3V for significant power savings. However, TFET performance and speed cannot meet requirement in a System on Chip (SoC), such as a CPU block, or speed path because (1) future integrated SoCs will still have to meet ˜3 GHz CPU speed; a TFET cannot meet this requirement due to fundamentally lower Idsat and lower speed versus conventional CMOS at higher Vdd (˜0.5V); (2) SoCx can take advantage of the super low power of TFET for blocks and circuits functions that does not need high speed, but low power is the essential requirement; and (3) the industry needs an innovative solution that can meet both power and performance requirements for future SoCs to be effective alternatives. Namely, a TFET with increased drivability and improved performance is needed.

Accordingly, there is a need for systems, apparatus, and methods that improve upon conventional CMOS approaches including the improved methods, system and apparatus provided hereby. The inventive features that are characteristic of the teachings, together with further features and advantages, are better understood from the detailed description and the accompanying figures. Each of the figures is provided for the purpose of illustration and description only, and does not limit the present teachings.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

Some examples of the disclosure are directed to systems, apparatus, and methods for increasing TFET drivability by optimizing vertical TFET integration and increasing an effective width of the TFET to improve the TFET performance.

In some examples of the disclosure, the system, apparatus, and method for a transistor device, includes: a plurality of gate elements; a plurality of source or drain elements extending parallel to the plurality of gate elements and horizontally spaced therefrom; and a plurality of fin elements extending parallel to the plurality of gate elements and vertically spaced therefrom, wherein each of the plurality of fin elements is horizontally spaced a first distance from each of the other ones of the plurality of fin elements.

In some examples of the disclosure, the system, apparatus, and method for a vertical integrated tunnel field effect transistor, includes: a plurality of gate elements, each of the plurality of gate elements having a gate contact at one end thereof; a plurality of source or drain elements extending parallel to the plurality of gate elements and horizontally spaced therefrom; a plurality of fin elements extending parallel to the plurality of gate elements and vertically spaced therefrom, wherein each of the plurality of fin elements is horizontally spaced a first distance from each of the other ones of the plurality of fin elements; and a plurality of active gate regions, each of the plurality of active gate regions formed by an overlap of one of the plurality of gate elements and one of the plurality of fin elements, and wherein each of the plurality of active gate regions has a horizontal width larger than a vertical height.

In some examples of the disclosure, the system, apparatus, and method for making a transistor device includes: patterning a substrate to form an N-well region and a P-well region; forming an N-well in the N-well region and a P-well in the P-well region; patterning the substrate to form a N+ diffusion region and a P+ diffusion region; forming an N+ diffusion well in the N+ diffusion region and a P+ diffusion well in the P+ diffusion region; forming a channel layer; opening a NFET region in the channel layer; opening a PFET region in the channel layer; depositing a oxide/silicon nitride film layer; forming a fin element in the oxide/silicon nitride film layer/substrate layer; depositing a silicon-oxide film; forming a dummy gate element on the silicon-oxide film; depositing an oxide source film and chemical mechanical polishing (CMP) process; remove dummy gate, deposit high-k dielectric and metal gate film, and CMP; forming a P source region and a N source region in the fins; depositing a dielectric layer; and forming a source contact and a drain contact in the dielectric layer.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary transistor device with double fin pitch in accordance with some examples of the disclosure.

FIG. 2 illustrates an exemplary transistor device with 4/3 fin pitch in accordance with some examples of the disclosure.

FIG. 3 illustrates an exemplary transistor device with the same fin pitch in accordance with some examples of the disclosure.

FIG. 4 illustrates a side view of an exemplary n-type transistor device in accordance with some examples of the disclosure.

FIG. 5 illustrates a side view of an exemplary p-type transistor device in accordance with some examples of the disclosure.

FIGS. 6A-C illustrate an exemplary partial process flow for making a transistor device in accordance with some examples of the disclosure.

FIG. 7 illustrates exemplary user equipment (UE) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein advantageously address the long-felt industry needs, as well as other previously unidentified needs, and mitigate shortcomings of the conventional methods, apparatus, and systems. For instance, the effective area of a transistor device according to one of the embodiments described herein may be increased by aligning the fin elements with the gate elements, which would improve the performance characteristics of the device.

The word “exemplary” is used herein to mean “serving as an example, instance, or illustration.” Any details described herein as “exemplary” is not necessarily to be construed as preferred or advantageous over other examples. Likewise, the term “examples” does not require that all examples include the discussed feature, advantage or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples only and is not intended to be limiting of examples of the disclosure. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element. Coupling and/or connection between the elements can be physical, logical, or a combination thereof. As employed herein, elements can be “connected” or “coupled” together, for example, by using one or more wires, cables, and/or printed electrical connections, as well as by using electromagnetic energy. The electromagnetic energy can have wavelengths in the radio frequency region, the microwave region and/or the optical (both visible and invisible) region. These are several non-limiting and non-exhaustive examples.

Any reference herein to an element using a designation such as “first,” “second,” and so forth does not limit the quantity and/or order of those elements. Rather, these designations are used as a convenient method of distinguishing between two or more elements and/or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” used in the description or the claims can be interpreted as “A or B or C or any combination of these elements.”

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the examples described herein, the corresponding form of any such examples may be described herein as, for example, “logic configured to” perform the described action.

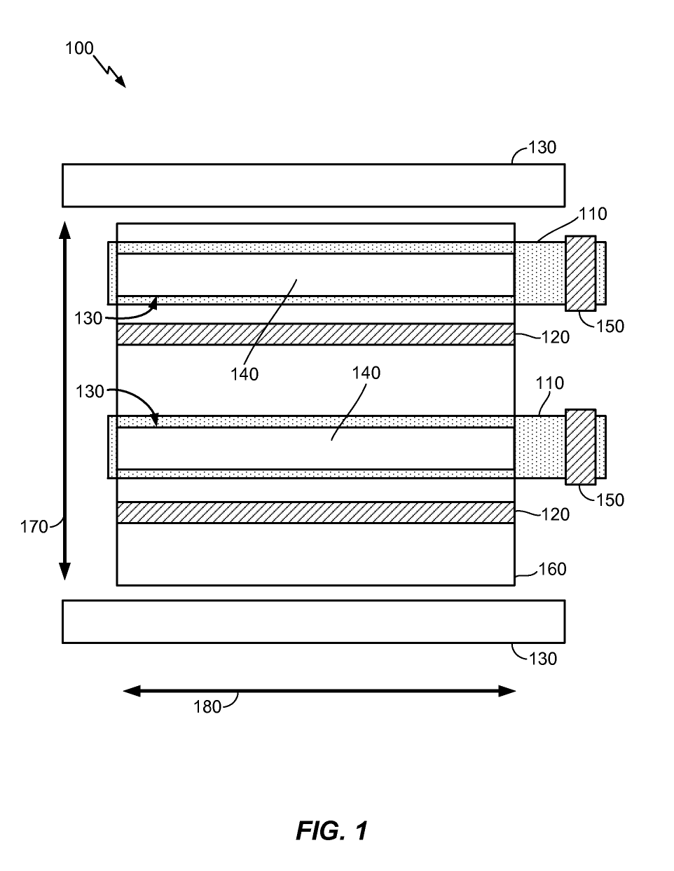

FIG. 1 illustrates an exemplary transistor device with double fin pitch in accordance with some examples of the disclosure. As shown in FIG. 1, a transistor device 100 may include a plurality of gate elements 110, a plurality of source or drain elements 120, and a plurality of fin elements 130. The plurality of gate elements 110 may be made of a metal gate (MG) or poly oxide (PO) material, for example. The plurality of source or drain elements 120 may be configured as a source or a drain depending on design requirements and may extend parallel to the plurality of gate elements 110 and may be horizontally spaced therefrom. The plurality of fin elements 130 may extend parallel to the plurality of gate elements and may be vertically spaced therefrom. Each of the plurality of fin elements 130 may be horizontally spaced a first distance from each of the other ones of the plurality of fin elements 130.

The transistor device 100 may also include a plurality of active gate regions 140 where each of the active gate regions 140 is formed by an overlap of one of the plurality of gate elements 110 and one of the plurality of fin elements 130. In addition, the transistor device 100 may include a plurality of gate contacts 150, each gate contact 150 on an end of one of the plurality of gate elements 110. The transistor device 100 may be analyzed by the measurements or ratios of fin versus gate pitch within the working area (active region or effective working area) 160 of the transistor device 100. The fin elements 130 outside the working area are dummy fins. The length 170 of the working area 160 and the width 180 of the working area 160 partially define the characteristics of the transistor device 100 along with the width and length of the fin elements 130 and gate elements 110. For instance, when length 170 is set to L=4×Fin Pitch and the width 180 is set to W=4×Gate (PO) Pitch, then:
W_{eff}=2n·PO_Pitch+2W_{fin}
Wₜₒₜₐₗ=m/2·W_{eff}=m·n(PO_Pitch+W_{fin}/n)
Ratio=0.5·(PO_Pitch/W_{fin}+1/n)/(W_{PO}/W_{fin}+1)
m fin height is m·Fin_pitch and
n finger width is n*PO_pitch, so the
area=m·n·Fin_pitch·PO_pitch.
m=4 fin and n=4 finger device
Wₜₒₜₐₗ=2W_{eff}=4·(4PO_Pitch+W_{fin})
For 10 nm node, PO_pitch=64 nm, W_{fin}=8 nm
Wₜₒₜₐₗ=4·(4PO_Pitch+W_{fin})=1056 nm
Ratio=0.5·(PO_Pitch/W_{fin}+1/n)/(W_{PO}/W_{fin}+1)
=0.5(8+1/4)/(1+1)≈2

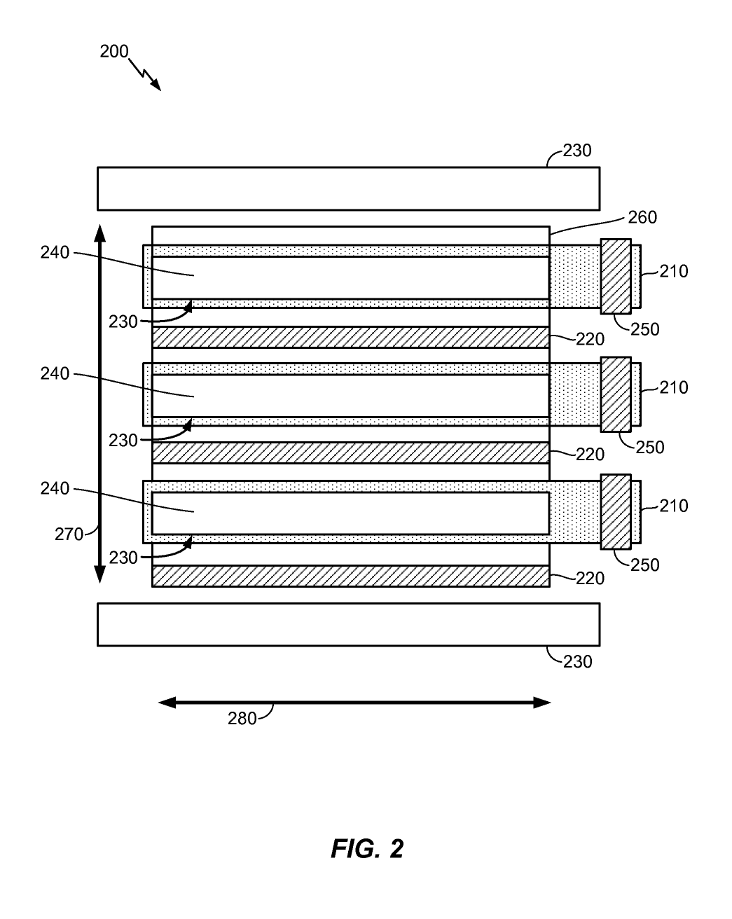

FIG. 2 illustrates an exemplary transistor device with 4/3 fin pitch in accordance with some examples of the disclosure. As shown in FIG. 2, a transistor device 200 may include a plurality of gate elements 210, a plurality of source or drain elements 220, and a plurality of fin elements 230. The plurality of gate elements 210 may be made of a metal gate (MG) or poly oxide (PO) material, for example. The plurality of source or drain elements 220 may be configured as a source or a drain depending on design requirements and may extend parallel to the plurality of gate elements 210 and may be horizontally spaced therefrom. The plurality of fin elements 230 may extend parallel to the plurality of gate elements and may be vertically spaced therefrom. Each of the plurality of fin elements 230 may be horizontally spaced a first distance from each of the other ones of the plurality of fin elements 230.

The transistor device 200 may also include a plurality of active gate regions 240 where each of the active gate regions 240 is formed by an overlap of one of the plurality of gate elements 210 and one of the plurality of fin elements 230. In addition, the transistor device 200 may include a plurality of gate contacts 250, each gate contact 250 on an end of one of the plurality of gate elements 210. The transistor device 200 may be analyzed by the measurements or ratios of fin versus gate pitch within the working area (active region or effective working area) 260 of the transistor device 200. The fin elements 230 outside the working area are dummy fins. The length 270 of the working area 260 and the width 280 of the working area 260 partially define the characteristics of the transistor device 200 along with the width and length of the fin elements 230 and gate elements 210. For instance, when length 270 is set to L=4×Fin Pitch and the width 280 is set to W=4×Gate (PO) Pitch, then:
W_{eff}=2n·PO_Pitch+2W_{fin}
Wₜₒₜₐₗ=3m/4·W_{eff}=3/2·m·n·(PO_Pitch+W_{fin}/n)
Ratio=0.75·(PO_Pitch/W_{fin}+1/n)/(W_{PO}/W_{fin}+1)
m fin height is m·Fin_pitch and
n finger width is n*PO_pitch, so the
area=m·n·Fin_pitch·PO_pitch.
m=4 fin and n=4 finger device
Wₜₒₜₐₗ=3W_{eff}=6·(4PO_Pitch+W_{fin})
For 10 nm node, PO_pitch=64 nm, W_{fin}=8 nm
Wₜₒₜₐₗ=6·(4PO_Pitch+W_{fin})=1584 nm
Ratio=0.75·(8+1/4)/(1+1)≈3

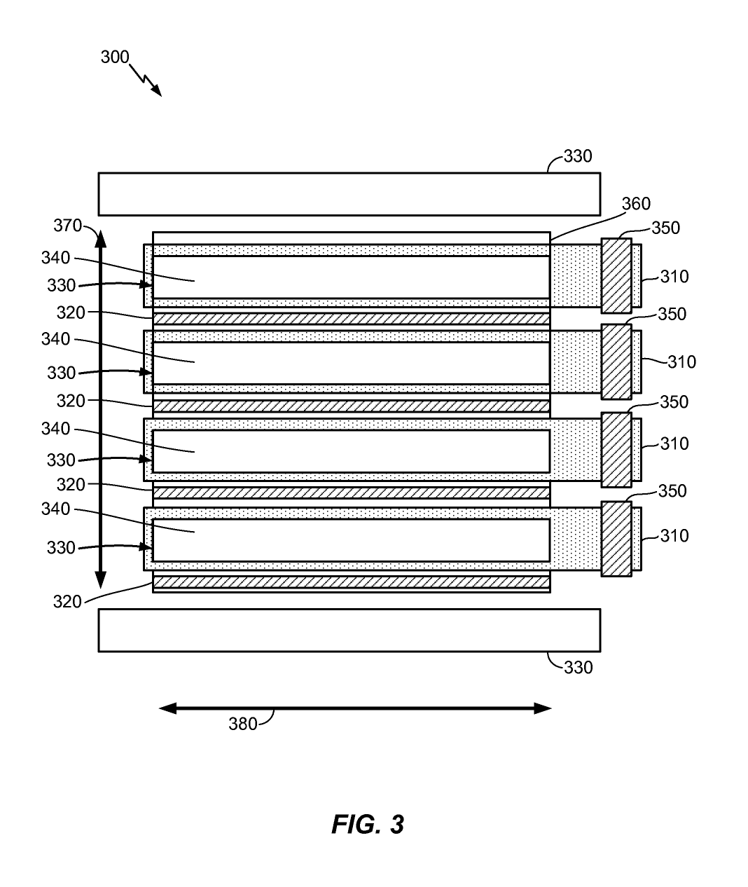

FIG. 3 illustrates an exemplary transistor device with the same fin pitch in accordance with some examples of the disclosure. As shown in FIG. 3, a transistor device 300 may include a plurality of gate elements 310, a plurality of source or drain elements 320, and a plurality of fin elements 330. The plurality of gate elements 310 may be made of a metal gate (MG) or poly oxide (PO) material, for example. The plurality of source or drain elements 320 may be configured as a source or a drain depending on design requirements and may extend parallel to the plurality of gate elements 310 and may be horizontally spaced therefrom. The plurality of fin elements 330 may extend parallel to the plurality of gate elements and may be vertically spaced therefrom. Each of the plurality of fin elements 330 may be horizontally spaced a first distance from each of the other ones of the plurality of fin elements 330.

The transistor device 300 may also include a plurality of active gate regions 340 where each of the active gate regions 340 is formed by an overlap of one of the plurality of gate elements 310 and one of the plurality of fin elements 330. In addition, the transistor device 300 may include a plurality of gate contacts 350, each gate contact 350 on an end of one of the plurality of gate elements 310. The transistor device 300 may be analyzed by the measurements or ratios of fin versus gate pitch within the working area (active region or effective working area) 360 of the transistor device 300. The fin elements 330 outside the working area are dummy fins. The length 370 of the working area 360 and the width 380 of the working area 360 partially define the characteristics of the transistor device 300 along with the width and length of the fin elements 330 and gate elements 310. For instance, when length 370 is set to L=4×Fin Pitch and the width 380 is set to W=4×Gate (PO) Pitch, then:
W_{eff}=2n·PO_Pitch+2W_{fin}
Wₜₒₜₐₗ=m·W_{eff}=2·m·n·(PO_Pitch+W_{fin}/n)
Ratio=(PO_Pitch/W_{fin}+1/n)/(W_{PO}/W_{fin}+1)
m fin height is m·Fin_pitch and
n finger width is n*PO_pitch, so the
area=m·n·Fin_pitch·PO_pitch.
m=4 fin and n=4 finger device
Wₜₒₜₐₗ=4W_{eff}=8·(4PO_Pitch+W_{fin})
For 10 nm node, PO_pitch=64 nm, W_{fin}=8 nm
Wₜₒₜₐₗ=8·(4PO_Pitch+W_{fin})=2112 nm
Ratio=(8+1/4)/(1+1)≈4

The different embodiments shown above may result in different characteristics when different scaling and dimensions are used as can be seen in below:

TABLE 1

| Technology | Fin Pitch/W/H | Gate Pitch/W | M0/M1 Pitch |
|---|---|---|---|
| (nm) | (nm) | (nm) | (nm) |
| 16/14 | 48/10/35 | 90/78 | 64 |
| 10 | 32/10/40 | 64/63 | 42 |
| 7 | 22/7/28 | 45/44 | 30 |
| 5 | 16/5/20 | 30 | 21 |

These different configurations result in the following improvements in width (PO is equivalent to Gate):

$$If {W}_{PO} / {W}_{fin} \approx 1 , PO\_pitch / {W}_{fin} \approx 6 , then$$

$$\begin{matrix}Device 100 \text{:} Ratio = 0.5 \cdot ( PO\_Pitch / {W}_{fin} + 1 / n ) / ( {W}_{PO} / {W}_{fin} + 1 ) \\ = 0.5 \cdot ( 6 + 1 / n ) / ( 1 + 1 ) \\ \approx 6 / 4 \\ \approx 1.5\end{matrix}$$

$$\begin{matrix}Device 200 \text{:} Ratio = 0.75 \cdot ( PO\_Pitch / {W}_{fin} + 1 / n ) / ( {W}_{PO} / {W}_{fin} + 1 ) \\ = 0.75 \cdot ( 6 + 1 / n ) / ( 1 + 1 ) \\ \approx 0.75 \cdot 6 / 2 \\ \approx 2.25\end{matrix}$$

$$\begin{matrix} Device 300 \text{:} Ratio = ( PO\_Pitch / {W}_{fin} + 1 / n ) / ( {W}_{PO} / {W}_{fin} + 1 ) \\ = ( 6 + 1 / n ) / ( 1 + 1 ) \\ \approx 6 / 2 \\ \approx 3\end{matrix}$$

Thus, various configurations using the embodiments described above may result in high drive current because the gate has the same orientation and pitch of as the active Fin region for a vertical TFET to have a large width. The manufacturing process is simple compared to a conventional finFET process due to re-arranging the gate orientation and the gate chemical mechanical polishing (CMP) process. Since the Fin is bar type, the Gate is all around the Fin from sidewall to form vertical all around TFET device. Thus, the effective width of TFET is increased and area utilization is more efficient.

Since the vertical TFET channel is in the vertical direction. The TFET gate length is controlled by channel film thickness. This avoids gate length patterning issues. Since it does not have high aspect ratio Fin structure to relax Fin, forming and gate/spacer etch processes are simpler. Also, the effective width relates to the Fin all around size instead of the Fin height.

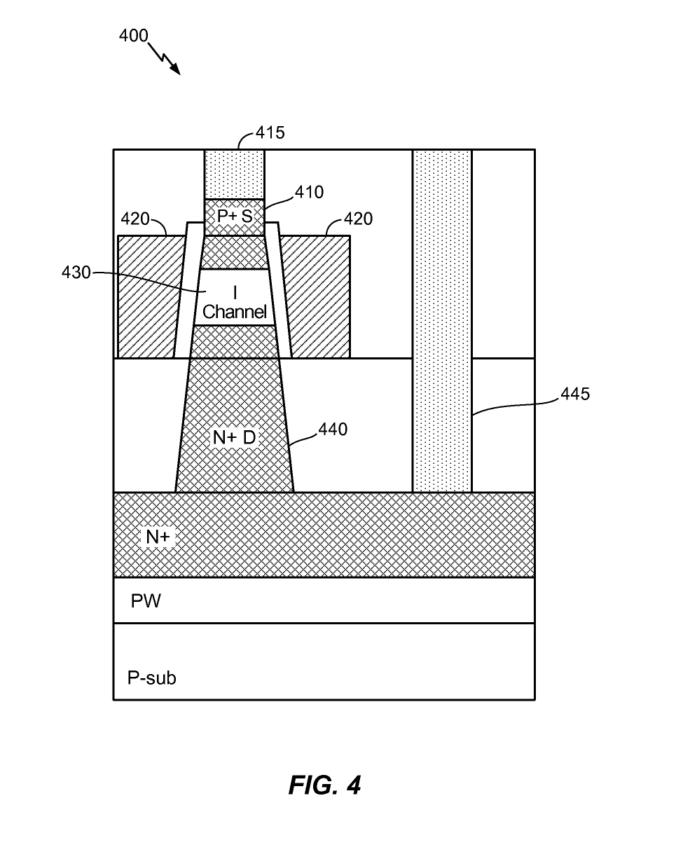

FIG. 4 illustrates a side view of an exemplary n-type transistor device in accordance with some examples of the disclosure. As shown in FIG. 4, a n-type transistor device 400 may include a source region 410 under a source contact 415, a gate structure 420 surrounding a current channel region 430, and a drain region 440 under the current channel region and connected to a drain contact 445.

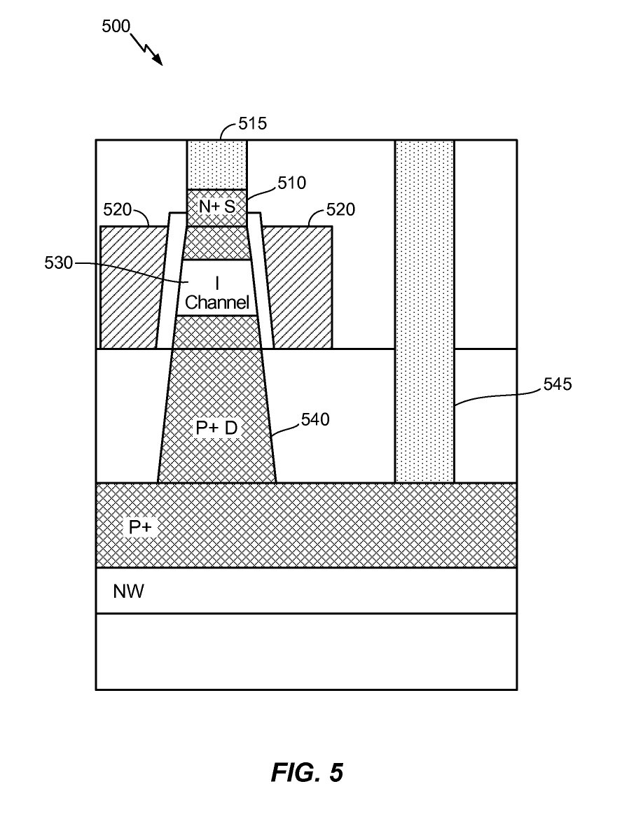

FIG. 5 illustrates a side view of an exemplary p-type transistor device in accordance with some examples of the disclosure. As shown in FIG. 5, a p-type transistor device 500 may include a source region 510 under a source contact 515, a gate structure 520 surrounding a current channel region 530, and a drain region 540 under the current channel region and connected to a drain contact 545.

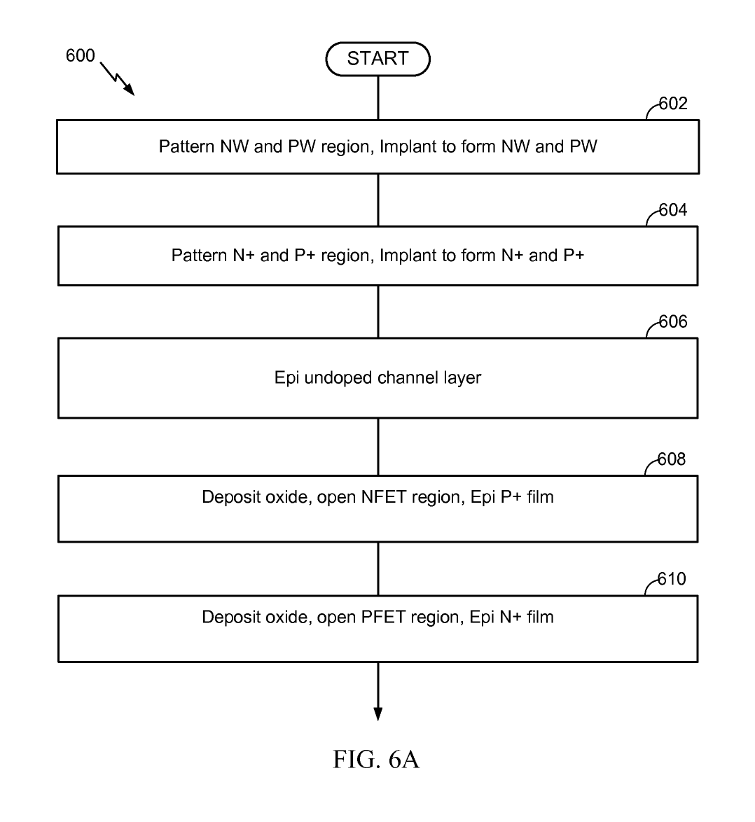

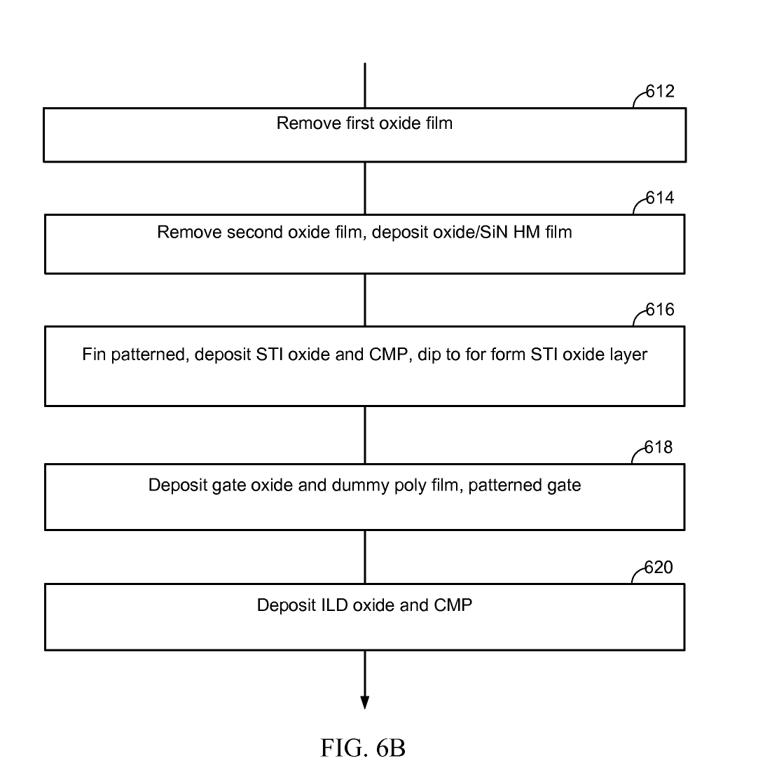

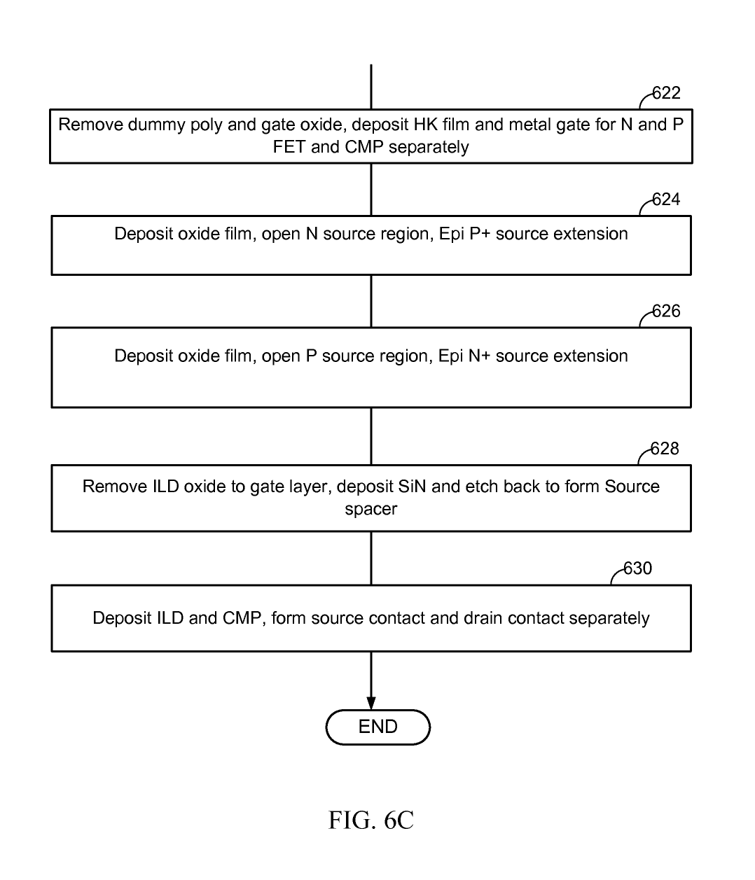

FIGS. 6A-C illustrate an exemplary partial process flow for making a transistor device in accordance with some examples of the disclosure. As shown in FIG. 6A, the partial process flow begins in 602 with patterning the N-well (NW) and P-well (PW) region of a substrate followed by ion implantation to form the NW and PW. Next in 604, the process continues with patterning the N+ diffusion and P+ diffusion region of the substrate followed by ion implantation to form the N+ diffusion well and P+ diffusion well (such as 440 in FIGS. 4 and 540 in FIG. 5). Next in 606, the channel layer is formed by epixtial (EPI) process to create an EPI undoped channel layer (such as 430 in FIGS. 4 and 530 in FIG. 5). Next in 608, a first oxide layer is deposited on the channel layer and then a NFET region is opened followed by the application of an EPI P+ film. In 610, a second oxide layer is deposited on the channel layer and then a PFET region is opened followed by the application of an EPI N+ film.

As shown in FIG. 6B, the process continues in 612 with removal of the first oxide film. Next in 614, the second oxide film is removed and an oxide/silicon nitride (SiN) hard mask (HM) film is applied. In 616, a fin is patterned then a shallow trench isolation (STI) oxide is applied before a chemical-mechanical planarization (CMP) process followed by dipping the structure to form an STI oxide layer. In 618, a gate oxide is deposited along with a dummy poly gate film and then patterned to form a gate (such as 420 in FIGS. 4 and 520 in FIG. 5). In 620, an interlayer dielectric (ILD) oxide is applied followed by a CMP process.

As shown in FIG. 6C, the process continues in 622 with the removal of the dummy poly gate film and gate oxide, depositing a high-K (HK) film and metal gate for N and P FET, and followed by separate CMP process for the gates. In 624, another oxide film is deposited, an N source region is opened, and the EPI P+ source extension is formed. In 626, another oxide film is deposited, a P source region is opened, and the EPI N+ source extension is formed. In 628, the ILD oxide to gate layer is removed, a SiN layer is deposited and then etched back to form a source spacer. In 630, the process concludes with depositing an ILD layer and application of a CMP process followed by the formation of the source contact (such as 415 in FIGS. 4 and 515 in FIG. 5) and the drain contact (such as 445 in FIGS. 4 and 545 in FIG. 5) separately.

In this description, certain terminology is used to describe certain features. The term “mobile device” can describe, and is not limited to, a mobile phone, a mobile communication device, a pager, a personal digital assistant, a personal information manager, a mobile hand-held computer, a laptop computer, a wireless device, a wireless modem, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

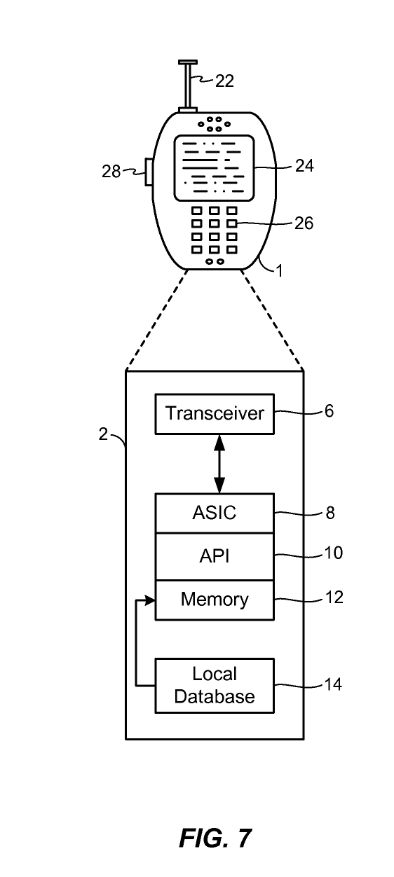

Referring to FIG. 7, a system 1 that includes a UE 1, (here a wireless device), such as a cellular telephone, which has a platform 2 that can receive and execute software applications, data and/or commands transmitted from a radio access network (RAN) that may ultimately come from a core network, the Internet and/or other remote servers and networks. Platform 2 can include transceiver 6 operably coupled to an application specific integrated circuit (“ASIC” 8), or other processor, microprocessor, logic circuit, or other data processing device. ASIC 8 or other processor executes the application programming interface (“API”) 10 layer that interfaces with any resident programs in memory 12 of the wireless device. Memory 12 can be comprised of read-only or random-access memory (RAM and ROM), EEPROM, flash cards, or any memory common to computer platforms. Platform 2 also can include local database 14 that can hold applications not actively used in memory 12. Local database 14 is typically a flash memory cell, but can be any secondary storage device as known in the art, such as magnetic media, EEPROM, optical media, tape, soft or hard disk, or the like. Internal platform 2 components can also be operably coupled to external devices such as antenna 22, display 24, push-to-talk button 28 and keypad 26 among other components, as is known in the art.

Accordingly, an example of the disclosure can include a UE including the ability to perform the functions described herein. As will be appreciated by those skilled in the art, the various logic elements can be embodied in discrete elements, software modules executed on a processor or any combination of software and hardware to achieve the functionality disclosed herein. For example, ASIC 8, memory 12, API 10 and local database 14 may all be used cooperatively to load, store and execute the various functions disclosed herein and thus the logic to perform these functions may be distributed over various elements. Alternatively, the functionality could be incorporated into one discrete component. Therefore, the features of UE 1 in FIG. 7 are to be considered merely illustrative and the disclosure is not limited to the illustrated features or arrangement.

The wireless communication between UE 1 and the RAN can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE) or other protocols that may be used in a wireless communications network or a data communications network.

Nothing stated or illustrated depicted in this application is intended to dedicate any component, step, feature, benefit, advantage, or equivalent to the public, regardless of whether the component, step, feature, benefit, advantage, or the equivalent is recited in the claims.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

Although some aspects have been described in connection with a device, it goes without saying that these aspects also constitute a description of the corresponding method, and so a block or a component of a device should also be understood as a corresponding method step or as a feature of a method step. Analogously thereto, aspects described in connection with or as a method step also constitute a description of a corresponding block or detail or feature of a corresponding device. Some or all of the method steps can be performed by a hardware apparatus (or using a hardware apparatus), such as, for example, a microprocessor, a programmable computer or an electronic circuit. In some examples, some or a plurality of the most important method steps can be performed by such an apparatus.

In the detailed description above it can be seen that different features are grouped together in examples. This manner of disclosure should not be understood as an intention that the claimed examples require more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods disclosed in the description or in the claims can be implemented by a device comprising means for performing the respective steps or actions of this method.

Furthermore, in some examples, an individual step/action can be subdivided into a plurality of sub-steps or contain a plurality of sub-steps. Such sub-steps can be contained in the disclosure of the individual step and be part of the disclosure of the individual step.

While the foregoing disclosure shows illustrative examples of the disclosure, it should be noted that various changes and modifications could be made herein without departing from the scope of the disclosure as defined by the appended claims. The functions, steps and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

1. A transistor device, comprising:
a plurality of gate elements;
a plurality of source or drain elements extending parallel to the plurality of gate elements and horizontally spaced therefrom; and
a plurality of fin elements extending parallel to the plurality of gate elements and vertically spaced therefrom, wherein each of the plurality of fin elements is horizontally spaced a first distance from each of the other ones of the plurality of fin elements.

2. The transistor device of claim 1, further comprising a plurality of active gate regions, each of the plurality of active gate regions formed by an overlap of one of the plurality of gate elements and one of the plurality of fin elements.

3. The transistor device of claim 2, wherein each of the plurality of active gate regions has a horizontal width larger than a vertical height.

4. The transistor device of claim 1, wherein the plurality of source or drain elements are source elements.

5. The transistor device of claim 1, wherein the plurality of source or drain elements are drain elements.

6. The transistor device of claim 1, wherein the first distance is twice a fin pitch of each of the plurality of fin elements.

7. The transistor device of claim 1, wherein the first distance is 4/3 a fin pitch of each of the plurality of fin elements.

8. The transistor device of claim 1, wherein the first distance is equal to a fin pitch of each of the plurality of fin elements.

9. The transistor device of claim 1, wherein the transistor device is a TFET.

10. The transistor device of claim 1, wherein the transistor device is a finFET.

11. The transistor device of claim 1, wherein a center to center distance between each of the plurality of fin elements is twice a fin pitch of one of the plurality of fin elements.

12. The transistor device of claim 1, wherein a center to center distance between each of the plurality of fin elements is 4/3 of a fin pitch of one of the plurality of fin elements.

13. The transistor device of claim 1, wherein each of the plurality of fin elements is a rectangular bar shape and each of the plurality of gate elements surrounds a respective one of the plurality of fin elements.

14. The transistor device of claim 1, wherein the plurality of gate elements are poly gate structures.

15. The transistor device of claim 1, wherein the transistor device is incorporated into a device selected from a group consisting of a set top box, a music player, a video player, an entertainment unit, a navigation device, a communications device, a personal digital assistant (PDA), a fixed location data unit, and a computer, and further including the device.

16. A vertical integrated tunnel field effect transistor, comprising:
a plurality of gate elements, each of the plurality of gate elements having a gate contact at one end thereof;
a plurality of source or drain elements extending parallel to the plurality of gate elements and horizontally spaced therefrom;
a plurality of fin elements extending parallel to the plurality of gate elements and vertically spaced therefrom, wherein each of the plurality of fin elements is horizontally spaced a first distance from each of the other ones of the plurality of fin elements; and
a plurality of active gate regions, each of the plurality of active gate regions formed by an overlap of one of the plurality of gate elements and one of the plurality of fin elements, and wherein each of the plurality of active gate regions has a horizontal width larger than a vertical height.

17. The vertical integrated tunnel field effect transistor of claim 16, wherein the first distance is one of twice a fin pitch of each of the plurality of fin elements, 4/3 the fin pitch of each of the plurality of fin elements, or equal to the fin pitch of each of the plurality of fin elements.

18. The vertical integrated tunnel field effect transistor of claim 17, wherein a center to center distance between each of the plurality of fin elements is one of twice the fin pitch of one of the plurality of fin elements, 4/3 of the fin pitch of one of the plurality of fin elements, or equal to the fin pitch of one of the plurality of fin elements.

19. A vertically integrated finFET device, comprising:
a plurality of gate elements, each of the plurality of gate elements having a gate contact at one end thereof;
a plurality of source-drain elements extending parallel to the plurality of gate elements and horizontally spaced therefrom;
a plurality of fin elements extending parallel to the plurality of gate elements and vertically spaced therefrom, wherein each of the plurality of fin elements is horizontally spaced a first distance from each of the other ones of the plurality of fin elements; and
wherein each of the plurality of fin elements is a rectangular bar shape and each of the plurality of gate elements surrounds a respective one of the plurality of fin elements.

20. The vertically integrated finFET device of claim 19, wherein the plurality of gate elements are poly gate structures.

21. A method of making a transistor device, the method comprising:
patterning a substrate to form an N-well region and a P-well region;
forming an N-well in the N-well region and a P-well in the P-well region;
patterning the substrate to form a N+ diffusion region and a P+ diffusion region;
forming an N+ diffusion well in the N+ diffusion region and a P+ diffusion well in the P+ diffusion region;
forming a channel layer;
opening a NFET region in the channel layer;
opening a PFET region in the channel layer;
depositing a oxide-silicon nitride film layer;
forming a fin element in the oxide-silicon nitride film layer;
depositing a silicon-oxide film;
forming a dummy gate element on the silicon-oxide film;
depositing an oxide film;
forming a P source region and a N source region in the oxide film;
depositing a dielectric layer; and
forming a source contact and a drain contact in the dielectric layer.

22. The method of claim 21, wherein forming the N-well and P-well includes ion implantation of the N-well region and the P-well region.

23. The method of claim 22, wherein forming the N+ diffusion well and the P+ diffusion well includes ion implantation of the N+ diffusion region and the P+ diffusion region.
